(19) United States
(12) Patent Application Publication
(10) Pub. No.: US 2020/0051897 A1
(43) Pub. Date: Feb. 13, 2020

(54) SEMICONDUCTOR PACKAGE

(71) Applicant: SHUN-PING HUANG, ZHUBEI CITY (TW)

(72) Inventor: SHUN-PING HUANG, ZHUBEI CITY (TW)

(21) Appl. No.: 16/655,843

(22) Filed: Oct. 17, 2019

Related U.S. Application Data
(63) Continuation-in-part of application No. 15/956,055, filed on Apr. 18, 2018, now Pat. No. 10,504,841.
(60) Provisional application No. 62/619,834, filed on Jan. 21, 2018.

(51) Int. Cl. H01L 23/495; H01L 23/498; H01L 23/522; H01L 23/00

(52) U.S. Cl. CPC H01L 23/49513; H01L 23/49816; H01L 23/49582; H01L 2224/02379; H01L 24/28; H01L 2224/02333; H01L 2224/02371; H01L 23/5226

(57) ABSTRACT

An embodiment method includes providing a fan-out package structure having cavities to confine semiconductor dies by applying adhesive material which has similar coefficient of thermal expansion (CTE) with semiconductor dies in the gap between the edges of dies and the edges of cavities. The method further includes forming a molding compound over a fan-out package structure with semiconductor dies, building fan-out redistribution layers over a fan-out package structure with semiconductor dies and electrically connected to the semiconductor dies.

### CROSS REFERENCE TO RELATED APPLICATION

This application is a continuation-in-part application of U.S. patent application Ser. No. 15/956,055 filed on, Apr. 18, 2018, which claims the priority benefit of U.S. Provisional Application Ser. No. 62/619,834, filed on Jan. 21, 2018, the full disclosure of which is incorporated herein by reference.

### BACKGROUND

### 1. Technical Field

The present disclosure relates to a fan-out package structure and method of improving current multiple dissimilar chips with different functions into a system or subsystem (SiP, System in Package) with thinner package dimension, better electrical performance, and cost-effectively.

### 2. Description of the Related Art

Fan-out package is a booming technology to achieve low-cost compact package solution for mobile application (SoC, System On a Chip) and even the high-end computing application (SiP, System in Package). A fan-out package structure is some kind of fixing frame which is made of material having similar coefficient of thermal expansion (CTE) with semiconductor dies such as silicon and glass. A fan-out package structure has cavities formed thereon to confine semiconductor dies therein. Furthermore, a fan-out package structure may have recesses to receive semiconductor dies partially. A fan-out package not only puts everything into a small package to reduce the cost but also shortens the distances of signal paths between chips to enhance the electrical performance and lower power consumption.

The cross-sectional views of the examples for multiple chips application in fan-out package is shown in FIG. 1. Foundry and OSAT manufacturer use wafer level or panel level as the high volume manufacturing (HVM) platform due to the concern of cost and efficiency. There are two major manufacturing methods in fan-out packaging for Multiple-Chips-Last and Multiple-Chips-First. The cross-sectional views of the examples for Multiple-Chips-Last and Multiple-Chips-First are shown in FIG. 2. Multiple-Chips-First method can provide thinner package dimension, less heat consumption, and better performance in electrical resistance than Multiple-Chips-Last method. These merits attract the high performance computing (HPC) application (SiP, System in Package) to attempt to adopt these fan-out Multiple-Chips-First method to avoid the high cost of typical 2.5D IC package, such as CoWoS (Chip on Wafer on Substrate), disclosed in U.S. Pat. No. 9,806,058 B2 to TSMC or other advanced heterogeneous integration, such as EMIB (Embedded Multi-die Interconnection Bridge), disclosed in US 2018/0005945 A1 and 3D IC package, (FOVEROS package) to INTEL. The cross-sectional views of the examples for CoWoS package and EMIB package are shown in FIG. 3. The cross-sectional view of the example for FOVEROS package is shown in FIG. 4.

Referring to FIG. 1, which illustrates a typical example for a dual-dies package 100 including a larger die 101 and a smaller die 102 and a multiple-dies package 180 including a thin die 103, a thicker die 104 and stacking dies 105 in a fan-out package. The dies 101, 102 in the package 100 and the dies 103, 104, 105 in the package 180 are embedded in wraps of epoxy molding compound (EMC) 110 and connect thin-film redistribution layers (RDLs) 120 with metal pads 130, respectively. On the other sides of the thin-film redistribution layers 120 are respectively placed with solder balls 140.

FIG. 2 illustrates a typical Multiple-Chips-Last fan-out package 200 and a Multiple-Chips-First fan-out package 280. In the package 200, dies including a larger die 201 and a smaller die 202 are embedded in a wrap of epoxy molding compound (EMC) 210. Metal pads 230 of the dies 201 and 202 connect a thin-film redistribution layer 220 by micro solder bumps 205, respectively. On the other side of the thin-film redistribution layer 220 is placed with solder balls 240. In the package 280, dies including a larger die 201 and a smaller die 202 are embedded in a wrap of epoxy molding compound (EMC) 210. Metal pads 230 of the dies 201 and 202 connect a thin-film redistribution layer directly without using any solder bumps. On the other side of the thin-film redistribution layer 220 is placed with solder balls 240.

FIG. 3 illustrates examples for CoWoS package 300 and EMIB package 380. In the package 300, dies including a die 301 and stacking dies 302 are embedded in a wrap of epoxy molding compound (EMC) 310. Metal pads 330 of the dies 301 and 302 connect a silicon interposer 340 by micro solder bumps 305, respectively. Silicon interposers 340 are of dummy silicon with through silicon vias (TSV) 345 embedded. The through silicon vias (TSV) 345 connect the electrical signal paths from the dies 301 and 302 to a PCB substrate 360. On the other side of the silicon interposer 340 are placed with micro solder balls 350 to connect the PCB substrate 360. Solder balls 370 are placed on the other side of the PCB substrate 360. In the package 380, dies including a die 301 and stacking dies 302 are embedded in a wrap of epoxy molding compound (EMC) 310. Silicon chiplets 365 are embedded in a PCB substrate 360. Metal pads 330 of the dies 301 and 302 connect the silicon chiplets 365 and PCB substrate 360 directly by micro solder bumps 305, respectively. In typical 2.×D IC package (CoWoS and EMIB), an interconnection path between the dies needs two solder joints. For example, each of the interconnection path between the dies 301 and 302 needs two micro solder bumps 305.

FIG. 4 illustrates an example for FOVEROS package 400. In the package 400, metal pads 430 of dies 401 and 402 connect an active silicon interposer 440 by micro solder bumps 405, respectively. The active silicon interposer 440 is of silicon IC with through silicon vias (TSV) 435 embedded. The through silicon vias (TSV) 435 connect the electrical signal paths from dies 401 and 402 to a PCB substrate 460. Metal pads 450 on the other side of the active interposer 440 connect a PCB substrate 460 by micro solder balls 445, respectively. On the other side of PCB substrate 460 are placed with solder balls 470, respectively.

The manufacturing challenges of current Multiple-Chips-First package mainly come from the compression molding process. Wafer/Panel level compression molding is one of the main fan-out manufacturing processes to build the reconfigured wafer/panel that precedes the thin-film redistribution layer processes. The epoxy molding compound (EMC) is used for fan-out interconnection fabrication, and the protection barrier against corrosive or humid environments. The accurate location of dies is required for high yield of the fine resolution thin-film redistribution layer process. A critical die dislocation issue during the molding process reduces the yield. The die shifting away from its original positions is normally observed during embedding. This situation will be getting more serious when transiting to the larger wafer/panel size. Significant misalignments will be caused due to the tiny die dislocation offset in the lithography process. The thin-film redistribution layer spacing requirement and device pad pitch are also impacted seriously. Therefore, the more demand of reducing package dimension has the more production yield is lost.

Three major factors that cause the die dislocation during the molding process are listed as below:
1. The coefficient of thermal expansion (CTE) mismatch of involved materials, such as dies, thin-film redistribution layer and epoxy molding compound (EMC) during temperature variation in the fabrication process;
2. The drag force from the mold flow during filling/compressing process; and
3. The epoxy molding compound (EMC) chemical shrinkage during multiple cure process of building thin-film redistribution layer.

There are some methods that attempt to improve the die dislocation during the single chip fan-out manufacturing processes, such as the embedded silicon carrier disclosed in WO 2017143782 A1 to Hua-Tian Technology (Kunshan) Electronics Co., Ltd, and the patterned carrier disclosed in U.S. Pat. No. 9,640,498 B1 to TSMC. But those above methods are not fully coverage of the above factors but also cannot handle the manufacturing of the multiple dies heterogeneous integration in a fan-out package. Normally heterogeneous integration is composed of dies without same dimension and height. In order to resolve the above problems, Maxim Integrated Products, Inc. provides a heterogeneous integration solution in silicon carrier which disclosed in US 2014/0252655 A1. But this high cost and proprietary manufacturing method cannot meet the high volume manufacturing (HVM) efficiency and cost of foundry and OSTA manufacturer expected. Moreover, this method still cannot provide better solution to improve the electrical performance and less power consumption.

### SUMMARY

An object of the present disclosure is to provide a semiconductor package and method of forming the same that is capable of avoiding dies (single-chip and multiple-chips) dislocation during the compression molding process of fan-out package manufacturing process. The semiconductor package and method of forming the same is capable of matching the original wafer level or panel level high volume manufacturing (HVM) platform of fan-out package manufacturing with better fabrication yield.

Another object of present disclosure is to provide a semiconductor package and method of forming the same that may enhance the finer features of thin-film redistribution layer by stopping the expose of epoxy molding compound (EMC) on the thin-film redistribution layer side of fan-out package manufacturing.

The last object of present disclosure is to provide a semiconductor package and method of forming the same that may integrate multiple dies in one package (SiP, System in Package) with more compact package dimension and better electrical performance interconnections.

In order to achieve the above objects, the semiconductor package and method of forming the same according to the present disclosure includes a fan-out package structure which has cavities formed thereon to confine semiconductor dies therein by filling the gaps between the edge of the dies and the edge of the cavities with adhesive that has similar coefficient of thermal expansion (CTE) with semiconductor dies. The adhesive may be composed of and mixed with glass powder, filler, binder and some additives. The adhesive may be low coefficient of thermal expansion (CTE) epoxy. The adhesive has similar and as close as the coefficient of thermal expansion (CTE) with semiconductor device chips/dies. The coefficient of thermal expansion (CTE) of the adhesive may be smaller than 10 ppm/° C. in comparison with the silicon's CTE of 2.6 ppm/° C. It is important to use a material having a similar coefficient of thermal expansion because it helps reduce the thermal and mechanical stresses in the joint interface. Moreover, the adhesive may not generate gas during the following thermal process. After heating and hardening the adhesive, the fan-out package structure with semiconductor dies according to the present disclosure will be jointed as firmly as one complete object such as wafer, panel, substrate or single die and has uniform thermal expansion during various processes (e.g., molding or building thin-film redistribution layer).

The semiconductor package according to the present disclosure includes a fan-out package structure that may have recesses to receive semiconductor dies partially. The dies partially disposed in the recesses may be attached on the recesses with the above-mentioned adhesive or solder joint in between. The fan-out package structure in the semiconductor package of the present disclosure may have through holes/vias to hold or contain the metal pillars or poles that interconnect the thin-film redistribution layer and semiconductor dies on the recesses electrically.

The fan-out package structure in the semiconductor package of the present disclosure may be in wafer, panel, substrate or single die form. The size of the cavities inside a fan-out package structure may be different and copes with the size of individual semiconductor die placed inside the cavity. After heating and hardening the adhesive, the fan-out package structure with semiconductor dies according to the present disclosure will be jointed as firmly as one complete object such as wafer, panel, substrate or single die. The complete object has high CTE uniformity and is easy to handle (e.g., moving, flipping and doing alignment) during various processes (e.g., molding or building thin-film redistribution layer).

After various features of the fan-out package are formed, the fan-out package structure with will be included in the semiconductor package. The top surface of the fan-out package structure may have some alignment marks to improve the device dies placement precisely during the pick and place process.

Therefore, the semiconductor package with a fan-out package structure according to the present disclosure has at least the following advantages:
1. The fan-out package structure confines the semiconductor dies firmly by using the adhesive which has similar coefficient of thermal expansion (CTE) with semiconductor dies to avoid the dies dislocation (such as dies shifting and protrusion) during the compression molding process. Therefore, the fan-out package structure improves the manufacturing yield of fan-out package manufacturing process.
2. The fan-out package structure confines the semiconductor dies with the adhesive firmly and reduces the expose of epoxy molding compound (EMC) on the thin-film redistribution layer side of the fan-out package. Therefore, the fan-out package structure and method according to the present disclosure may improve the topology of surface on the thin-film redistribution layer side and extent to finer features of thin-film redistribution layer.
3. The fan-out package structure not only shortens the electrical signal path but also reduces or eliminates the solder joints or solder in the electrical signal path. Therefore, the fan-out package structure may provide multiple dies integrated in one fan-out package with better electrical performance interconnections and less thermal consumption. Moreover, the fan-out package structure shortens the electrical signal path and also reduces the package dimension.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view illustrating a typical example of multiple chips application in fan-out package.

FIG. 2 illustrates cross-sectional views of the examples for Multiple-Chips-Last fan-out package and Multiple-Chips-First fan-out package.

FIG. 3 illustrates cross-sectional views of the examples for CoWoS package and EMIB package.

FIG. 4 is a cross-sectional view of the example for FORVEROS package.

FIG. 5 illustrates cross-sectional views of the examples of dual chips and multiple chips application in fan-out package with a fan-out package structure according to the present disclosure.

FIGS. 6-1 and 6-2 are block and cross-sectional views respectively to illustrate the examples of single Chip-First fan-out package with a fan-out package structure in wafer form according to the present disclosure.

FIG. 7-1 is a block view to illustrate the example of Multiple-Chips-First fan-out package with a fan-out package structure in wafer form according to the present disclosure.

FIGS. 7-2 and 7-3 are cross-sectional views respectively to illustrate the examples of Multiple-Chips-First fan-out package with a fan-out package structure according to the present disclosure.

### DETAILED DESCRIPTION OF THE PREFERRED EMBODIMENT

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

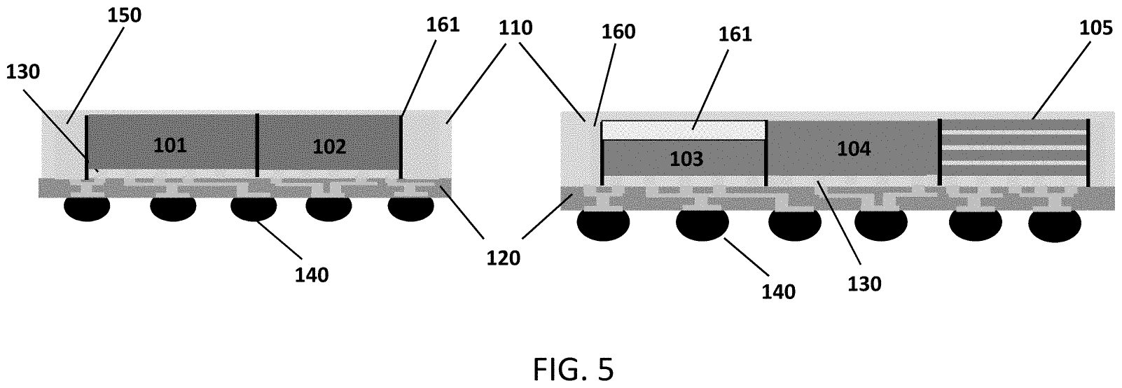

FIG. 5 illustrates the examples of dual chips and multiple chips application in fan-out package with a fan-out package structure according to the present disclosure. Dies 101 and 102 are respectively confined and fixed in cavities of a fan-out package structure 150 by applying an adhesive 161. The adhesive 161 is provided to surround and directly contact lateral surfaces of the dies 101 and 102. Multiple dies including a thin die 103, a thicker die 104, and stacking dies 105 are respectively confined and fixed in cavities of a fan-out package structure 160 by applying the adhesive 161. The adhesive 161 is provided to surround and directly contact lateral surfaces of the dies 103, 104 and 105. The fan-out package structure 150 with the dual dies (dies 101 and 102) and the fan-out package structure 160 with the multiple dies including the thin die 103, the thicker die 104 and the stacking dies 105 are embedded in wraps of epoxy molding compound (EMC) 110 and connect to thin-film redistribution layers (RDLs) 120, respectively. The dies 101, 102, 103, 104 and 105 are electrically connected to the thin-film redistribution layers 120 with metal pads 130, respectively. On the other sides of the thin-film redistribution layers 120 are placed with solder balls 140, respectively. It is to be noted that in this package configuration shown in FIG. 5, the interconnection paths between the dies 101 and 102 do not need any micro solder bumps but only the metal pads 130 and thin-film redistribution layer 120. Similarly, the interconnection paths between the dies 103, 104 and 105 also do not need any micro solder bumps but only the metal pads 130 and thin-film redistribution layer 120.

The adhesive 161 may be an epoxy adhesive or be composed of and mixed with glass powder, filler, binder and some additives. The adhesive 161 may be low coefficient of thermal expansion (CTE) epoxy. The adhesive 161 has similar and as close as the coefficient of thermal expansion (CTE) with the dies 101-105. The coefficient of thermal expansion (CTE) of the adhesive 161 may be smaller than 10 ppm/° C. in comparison with the silicon's CTE of 2.6 ppm/° C. It is important to use a material having a similar coefficient of thermal expansion because it helps reduce the thermal and mechanical stresses in the joint interface. Moreover, the adhesive 161 may not generate gas during the following thermal process. After heating and hardening the adhesive 161, the fan-out package structures 150, 160 with the dies 101-105 will be jointed as firmly as one complete object and has uniform thermal expansion during various processes.

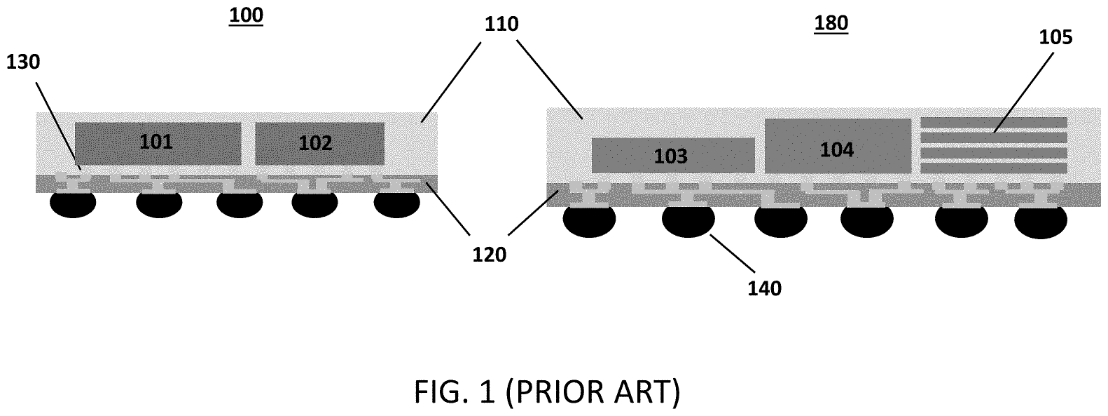

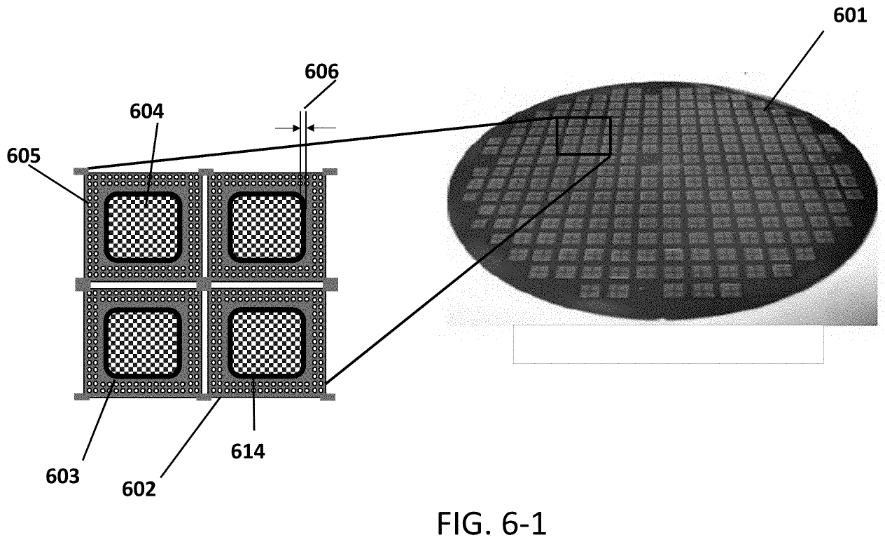

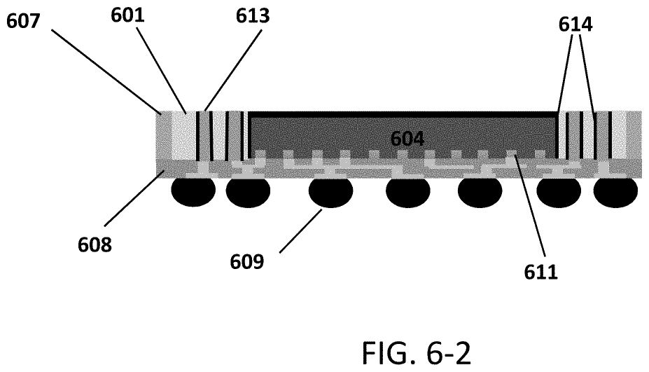

FIGS. 6-1 and 6-2 are block and cross-sectional views respectively to illustrate the example of single Chip-First fan-out package application according to the present disclosure. Referring to FIG. 6-1, a fan-out package structure 601 in wafer form includes many blocks 602, wherein each of the blocks 602 has a die 604 disposed and fixed in one of cavities 603 by applying an adhesive 614. A plurality of through vias/holes 605 is formed on the fan-out package structure 601 and located around the cavities 603. The gap 606 between the die 604 and the cavity 603 may be filled with the adhesive 614 that has similar coefficient of thermal expansion (CTE) with the die 604 and fan-out package structure 601. The adhesive 614 may cover the top surface of the die 604 and surround the lateral surfaces of the die 604. It is to be noted that through-package interconnections (TPI) made of conductive metal material, such as solder paste or metal powder may be preformed inside the through/vias/holes 605 before the dies 604 are disposed in the cavities 603.

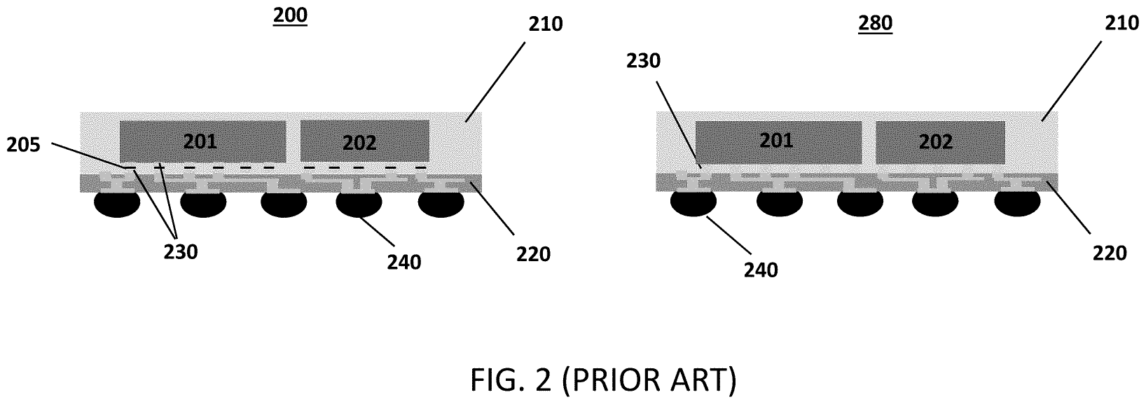

Referring to FIG. 6-2, a single die 604 is confined and fixed in a cavity of a fan-out package structure 601 by applying an adhesive 614. The adhesive 614 is provided to cover a top of the die 604 and surround lateral surfaces of the die 604. The fan-out package structure 601 with the die 604 is embedded in a wrap of an epoxy molding compound (EMC) 607 and connects to a thin-film redistribution layer 608. The die 604 is electrically connected to the thin-film redistribution layer 608 with metal pads 611. On the other side of the thin-film redistribution layer 608 is placed with solder balls 609. Through-package interconnections (TPI) 613 penetrate the fan-out package structure 601 and electrically connect to the metal pads of the redistribution layer 608.

The adhesive 614 may be an epoxy adhesive or be composed of and mixed with glass powder, filler, binder and some additives. The adhesive 614 may be low coefficient of thermal expansion (CTE) epoxy. The adhesive 614 has similar and as close as the coefficient of thermal expansion (CTE) with the die 604. The coefficient of thermal expansion (CTE) of the adhesive 614 may be smaller than 10 ppm/° C. in comparison with the silicon's CTE of 2.6 ppm/° C. It is important to use a material having a similar coefficient of thermal expansion because it helps reduce the thermal and mechanical stresses in the joint interface. Moreover, the adhesive 614 may not generate gas during the following thermal process. After heating and hardening the adhesive 614, the fan-out package structure 601 with the die 604 will be jointed as firmly as one complete object and has uniform thermal expansion during various processes.

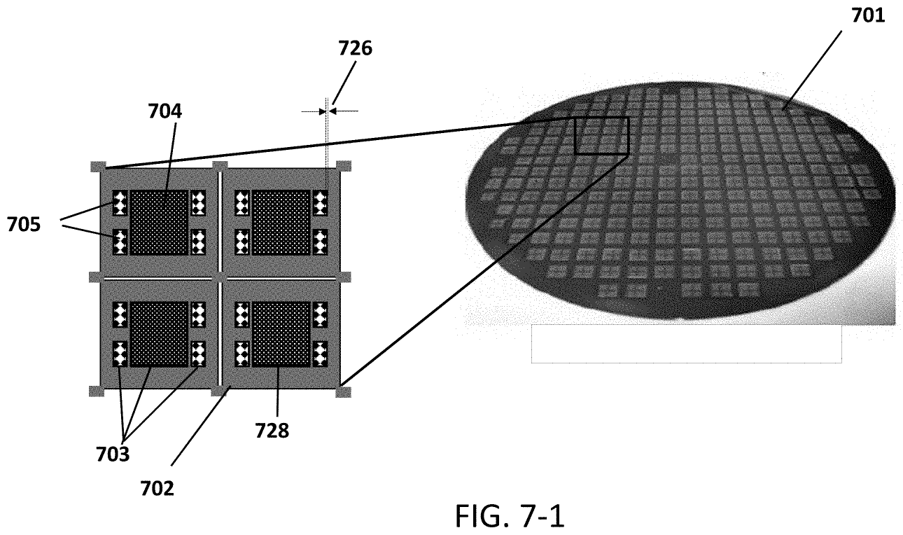

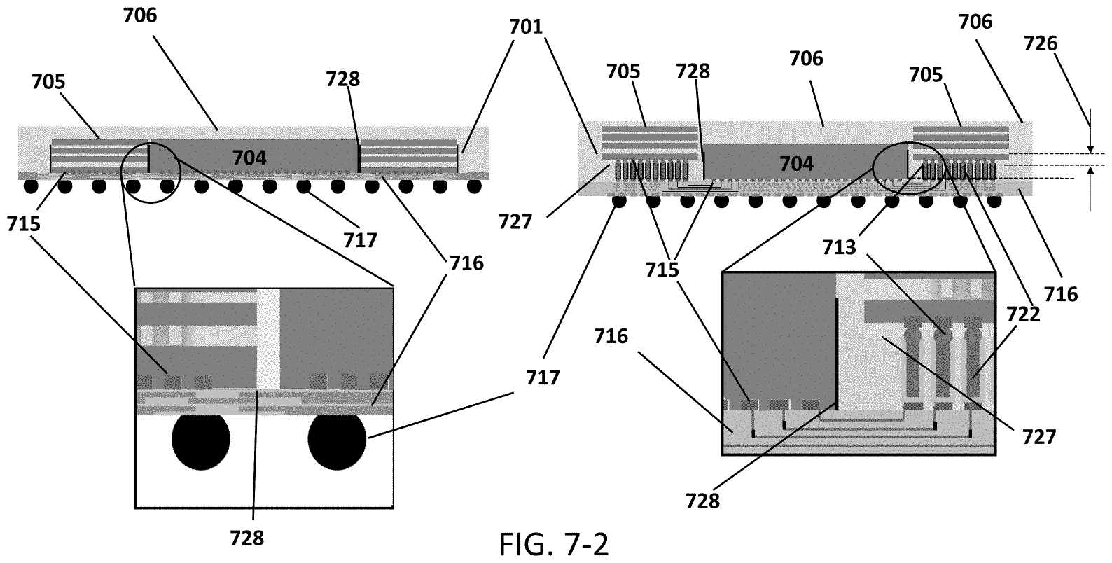

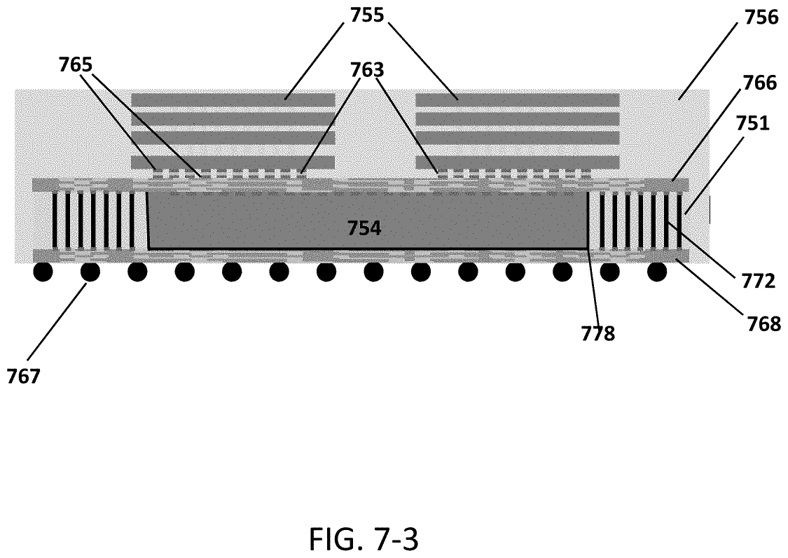

FIG. 7-1 is a block view to illustrate the example of Multiple-Chips-First fan-out package application according to the present disclosure. Referring to FIG. 7-1, a fan-out package structure 701 in wafer form includes many blocks 702, wherein each of the blocks 702 has a large semiconductor die 704 and small stacking semiconductor dies 705 disposed in one of cavities 703 respectively by applying an adhesive 728. The gap 726 between the edges of the dies 704, 705 and the edge of the cavity 703 may be filled with the adhesive 728 that has similar coefficient of thermal expansion (CTE) with the dies 704, 705 and the fan-out package structure 701.

FIG. 7-2 is a cross-sectional view to illustrate the examples of Multiple-Chips-First fan-out package application according to the present disclosure. Referring to the left portion of FIG. 7-2, a large die 704 and small stacking dies 705 are confined and fixed in the corresponding cavities of the fan-out package structure 701 by applying the adhesive 728 that has similar coefficient of thermal expansion (CTE) with the dies 704, 705 and the fan-out package structure 701. The fan-out package structure 701 with the dies 704, 705 is embedded in the wrap of an epoxy molding compound (EMC) 706 and connects to a thin-film redistribution layer 716. The dies 704 and 705 are electrically connected to metal pads 715 of the thin-film redistribution layer 716, respectively. On the other side of the thin-film redistribution layer 716 is placed with solder balls 717. In this package configuration shown at the left portion of FIG. 7-2, the interconnection paths between the dies 704 and 705 do not need any micro solder bumps but only metal pads 715.

Referring to the right portion of FIG. 7-2, a large die 704 is confined and fixed in the cavity of a fan-out package structure 701 by applying an adhesive 728 that has similar coefficient of thermal expansion (CTE) with the die 704. Through-package interconnections (TPIs) 722 made of conductive metal material, such as solder paste or metal powder are embedded in the fan-out package structure 701 and preformed inside through vias/holes before the die 704 is disposed in the cavity. The through-package interconnections (TPIs) 722 are provided to electrically connect metal pads 715 of the small stacking dies 705 to metal pads 715 of a thin-film redistribution layer 716 disposed below the fan-out package structure 701. The small stacking dies 705 are placed on the top of corresponding recesses 727 of the fan-out package structure 701. The metal pads 715 located at the bottom of the stacking dies 705 are respectively jointed to tops of metal interconnections 722 with solder balls 713 disposed in between. The fan-out package structure 701 with the dies 704, 705 is embedded in the wrap of an epoxy molding compound (EMC) 706 and connects to the thin-film redistribution layer 716. The die 704 is electrically connected to the metal pads 715 of the thin-film redistribution layer 716. On the other side of the thin-film redistribution layer 716 is placed with solder balls 717. In the package configuration shown at the right portion of FIG. 7-2, each of the interconnection paths between the dies 704 and 705 needs only one solder joint.

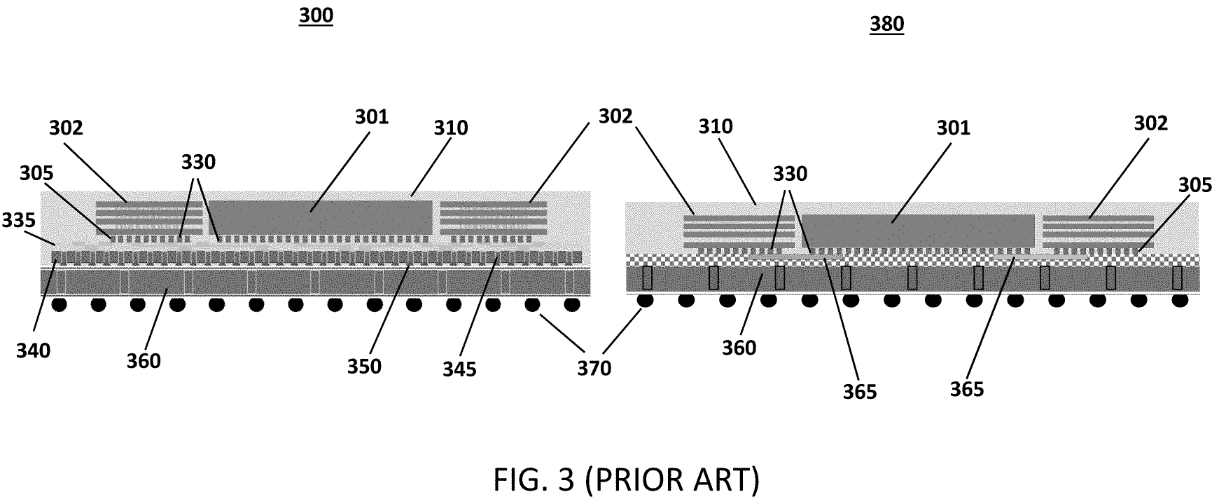

The adhesive 728 is provided to surround and directly contact lateral surfaces of the dies 704 and 705. The adhesive 728 may be an epoxy adhesive or be composed of and mixed with glass powder, filler, binder and some additives. The adhesive 728 may be low coefficient of thermal expansion (CTE) epoxy. The adhesive 728 has similar and as close as the coefficient of thermal expansion (CTE) with the dies 704, 705. The coefficient of thermal expansion (CTE) of the adhesive 728 may be smaller than 10 ppm/° C. in comparison with the silicon's CTE of 2.6 ppm/° C. It is important to use a material having a similar coefficient of thermal expansion because it helps reduce the thermal and mechanical stresses in the joint interface. Moreover, the adhesive 728 may not generate gas during the following thermal process. After heating and hardening the adhesive 728, the fan-out package structure 701 with the dies 704, 705 will be jointed as firmly as one complete object and has uniform thermal expansion during various processes. Therefore, the interconnection paths between the dies that shown in FIG. 7-2 have shorter paths and less solder joints than the interconnection paths between the dies shown in FIG. 3. The fan-out package structure 701 with recesses 727 can not only shorten the electrical signal paths but also reduce or eliminate the solder joints or solder in the electrical signal path between the dies 704 and 705.

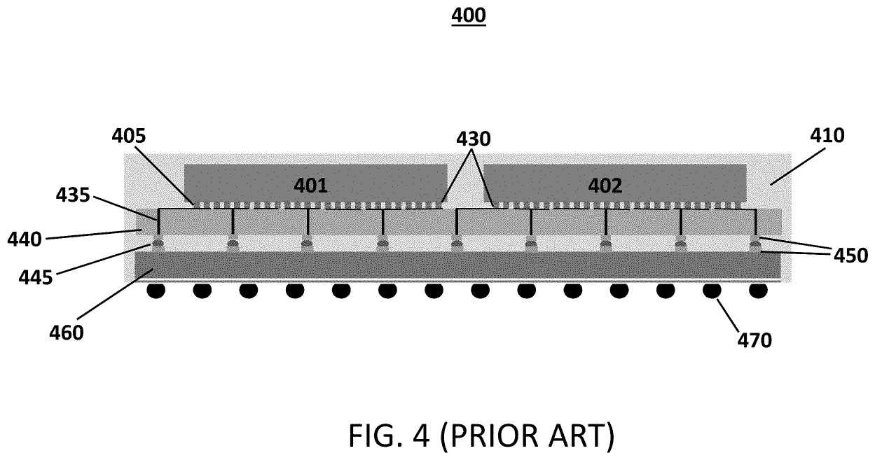

FIG. 7-3 is a cross-sectional view to illustrate the example of Multiple-Chips-First fan-out package application according to the present disclosure. Referring to FIG. 7-3, a large die 754 is face-up positioned and fixed in a cavity of a fan-out package structure 751 by applying an adhesive 778 that has similar coefficient of thermal expansion (CTE) with the die 754. The adhesive 778 is provided to surround and directly contact lateral surfaces of the die 754. A top thin-film redistribution layer 766 is disposed above the fan-out package structure 751 and electrically connected to a top of the die 754. Through-package interconnections (TPIs) 772 made of conductive metal material, such as solder paste or metal powder are embedded in the fan-out package structure 751 and preformed inside through vias/holes before the die 754 is disposed in the cavity. The through-package interconnections (TPIs) 772 are the electrical connection paths between the top thin-film redistribution layer 766 disposed on the fan-out package structure 751 and the bottom thin-film redistribution layer 768 disposed below the fan-out package structure 751. Small stacking dies 755 are placed in a face-down fashion on the top thin-film redistribution layer 766. Metal pads 765 located at the bottom of the stacking dies 755 are jointed to metal pads 765 of the top thin-film redistribution layer 766 with micro solder bumps 763 disposed in between. The fan-out package structure 751 with the dies 754, 755 is embedded in the wrap of an epoxy molding compound (EMC) 756 and connects to the bottom thin-film redistribution layer 768. On the other side of the bottom thin-film redistribution layer 768 are placed with solder balls 767. The small stacking dies 755 are electrically connected to the solder balls 767 by the metal pads 765, the top thin-film redistribution layer 766, the through-package interconnections 772 and the bottom thin-film redistribution layer 768 in sequence. Therefore, the interconnection between the dies 754 and 755 shown in FIG. 7-3 have shorter paths and less solder joints than the interconnection paths between the active silicon interposer 440 and dies 401, 402 that shown in FIG. 4. Moreover, the package of configuration including the die 754 with the top thin-film redistribution 766 and the bottom thin-film redistribution 768 in FIG. 7-3 shows much more compact than the package of configuration including the active silicon interposer 440 with the PCB substrate 460 in FIG. 4.

The adhesive 778 may be an epoxy adhesive or be composed of and mixed with glass powder, filler, binder and some additives. The adhesive 778 may be low coefficient of thermal expansion (CTE) epoxy. The adhesive 778 has similar and as close as the coefficient of thermal expansion (CTE) with the dies 754, 755. The coefficient of thermal expansion (CTE) of the adhesive 778 may be smaller than 10 ppm/° C. in comparison with the silicon's CTE of 2.6 ppm/° C. It is important to use a material having a similar coefficient of thermal expansion because it helps reduce the thermal and mechanical stresses in the joint interface. Moreover, the adhesive 778 may not generate gas during the following thermal process. After heating and hardening the adhesive 778, the fan-out package structure 751 with the dies 754, 755 will be jointed as firmly as one complete object and has uniform thermal expansion during various processes.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A semiconductor package, comprising:
a fan-out package structure having a first cavity formed thereon;
a first die disposed in the first cavity of the fan-out package structure;
an adhesive hardened in the first cavity of the fan-out package structure, the adhesive surrounding the first die to fix the first die in the first cavity of the fan-out package structure; and
a molding compound formed over the fan-out package structure.

2. The semiconductor package as claimed in claim 1, further comprising:
a redistribution layer disposed under the fan-out package structure;
metal pads disposed between the first die and the redistribution layer, wherein the metal pads are electrically connected to the first die and the redistribution layer; and
solder balls disposed under the redistribution layer.

3. The semiconductor package as claimed in claim 2, wherein the fan-out package structure further has a second cavity formed thereon, the semiconductor package further comprising:
a second die disposed in the second cavity of the fan-out package structure and electrically connected to the redistribution layer by metal pads.

4. The semiconductor package as claimed in claim 1, further comprising:
a redistribution layer disposed under the fan-out package structure; and
through-package interconnections formed around the first die, wherein the through-package interconnections penetrate the molding compound and the fan-out package structure to electrically connect to the redistribution layer.

5. The semiconductor package as claimed in claim 4, further comprising:
metal pads disposed between the first die and the redistribution layer, wherein the metal pads are electrically connected to the first die and the redistribution layer.

6. The semiconductor package as claimed in claim 1, wherein the fan-out package structure further has a recess formed thereon, the semiconductor package further comprising:
a second die disposed on a top of the recess;
a redistribution layer disposed under the fan-out package structure;
first metal pads disposed on a bottom of the second die;
second metal pads disposed on a top of the redistribution layer;
through-package interconnections formed under the second die and embedded in the fan-out package structure; and
solder balls jointing the first metal pads to tops of the through-package interconnections, respectively,
wherein the second die is electrically connected to the redistribution layer by the through-package interconnections.

7. The semiconductor package as claimed in claim 1, further comprising:
a top redistribution layer disposed above the fan-out package structure and electrically connected to a top of the first die; and
a second die disposed above the top redistribution layer.

8. The semiconductor package as claimed in claim 7, further comprising:
first metal pads disposed on a bottom of the second die;
second metal pads disposed on a top of the top redistribution layer; and
micro solder bumps jointing the first metal pads to the second metal pads, respectively.

9. The semiconductor package as claimed in claim 7, further comprising:
a bottom redistribution layer disposed under the fan-out package structure; and
through-package interconnections embedded in the fan-out package structure to electrically connect the top redistribution layer to the bottom redistribution layer.

10. The semiconductor package as claimed in claim 1, further comprising:
a top redistribution layer disposed above the fan-out package structure;
a bottom redistribution layer disposed under the fan-out package structure; and
through-package interconnections embedded in the fan-out package structure to electrically connect the top redistribution layer to the bottom redistribution layer.

11. The semiconductor package as claimed in claim 1, further comprising:
a second die disposed in the first cavity of the fan-out package structure and next to the first die, wherein the adhesive further surrounds the second die to fix the second die in the first cavity of the fan-out package structure.

12. The semiconductor package as claimed in claim 1, wherein the adhesive has a coefficient of thermal expansion (CTE) that is smaller than 10 ppm/° C.

13. The semiconductor package as claimed in claim 12, wherein the adhesive is an epoxy adhesive or is mixed with glass powder.
